(19) United States
(12) Patent Application Publication
(10) Pub. No.: US 2025/0391460 A1
(43) Pub. Date: Dec. 25, 2025

(54) NEGATIVE VOLTAGE GENERATOR AND MEMORY DEVICE INCLUDING THE SAME

(71) Applicant: SAMSUNG ELECTRONICS CO., LTD., Suwon-si (KR)

(72) Inventors: Hongil Yoon, Seoul (KR); Taegun Yim, Seoul (KR)

(73) Assignees: SAMSUNG ELECTRONICS CO., LTD., Suwon-si (KR); UIF (UNIVERSITY INDUSTRY FOUNDATION), YONSEI UNIVERSITY, Seoul (KR)

(21) Appl. No.: 19/082,970

(22) Filed: Mar. 18, 2025

(30) Foreign Application Priority Data
Jun. 20, 2024 (KR) 10-2024-0080290

(51) Int. Cl. G11C 11/4074; G11C 5/10; G11C 11/4076

(52) U.S. Cl. CPC G11C 11/4074; G11C 5/10; G11C 11/4076

(57) ABSTRACT

A negative voltage generator includes a first pumping capacitor, a second pumping capacitor, a voltage outputting circuit, a first discharging circuit and a second discharging circuit. The first pumping capacitor is connected between a first input node receiving an inverted clock signal and a first pumping node. The second pumping capacitor is connected between a second input node receiving a clock signal and a second pumping node. The voltage outputting circuit is connected to the first pumping node, the second pumping node and an output node outputting a negative voltage, and generates the negative voltage based on the clock signal and the inverted clock signal. The first and second discharging circuits discharge the first and second pumping nodes, respectively. The first discharging circuit includes a first NMOS transistor and a first inverter. The first NMOS transistor is connected between the first pumping node and a ground voltage. The first inverter controls a voltage of a gate electrode of the first NMOS transistor.

### CROSS-REFERENCE TO RELATED APPLICATION

This application is based on and claims priority under 35 U.S.C. § 119 to Korean Patent Application No. 10-2024-0080290 filed on Jun. 20, 2024 in the Korean Intellectual Property Office, the contents of which are herein incorporated by reference in their entirety.

### BACKGROUND

### 1. Field

Example embodiments of the disclosure relate generally to semiconductor integrated circuits, and more particularly, to negative voltage generators and memory devices including the negative voltage generators.

### 2. Description of Related Art

Semiconductor memory devices may be divided into two categories depending upon whether or not they retain stored data when disconnected from a power supply. These categories include volatile memory devices, which lose stored data when disconnected from power, and nonvolatile memory devices, which retain stored data when disconnected from power. While volatile memory devices may perform read and write operations at a high speed, content stored in the volatile memory devices may be lost at power-off. On the other hand, since nonvolatile memory devices retain stored content even at power-off, the nonvolatile memory devices may be used to store data that needs to be retained. Recently, the need for low power and reliability is increasing, and the power supply voltage of semiconductor memory devices is decreasing.

Volatile memory devices, such as dynamic random access memories (DRAMs), may include back-bias voltage generators. A back-bias voltage generator may apply a negative voltage to a bulk terminal of a cell transistor or access transistor of a DRAM, and a threshold voltage of the cell transistor or access transistor may increase. Therefore, a leakage current occurring by a storage node and storage capacitor may be reduced, and data may be retained for a relatively long period of time without leakage.

### SUMMARY

One or more aspects of the disclosure provide a negative voltage generator capable of having relatively fast operating speed, high current supply capability and low power consumption.

One or more aspects of the disclosure also provide a memory device including the negative voltage generator capable of having improved performance.

According to an aspect of the disclosure, there is provided a negative voltage generator including a first pumping capacitor connected between a first input node and a first pumping node, the first input node being configured to receive an inverted clock signal; a second pumping capacitor connected between a second input node and a second pumping node, the second input node being configured to receive a clock signal; a voltage outputting circuit connected to the first pumping node, the second pumping node and an output node, the voltage outputting circuit being configured to generate the negative voltage based on the clock signal and the inverted clock signal, and the output node being configured to output the negative voltage; a first discharging circuit configured to discharge the first pumping node; and a second discharging circuit configured to discharge the second pumping node, and wherein the first discharging circuit includes: a first n-type metal oxide semiconductor (NMOS) transistor connected between the first pumping node and a ground voltage, and including a gate electrode; and a first inverter configured to control a voltage of the gate electrode of the first NMOS transistor.

According to another aspect of the disclosure, there is provided a memory device including: a memory cell array including a plurality of memory cells; and a negative voltage generator configured to provide a negative voltage to the plurality of memory cells, the negative voltage generator including: a first pumping capacitor connected between a first input node and a first pumping node, the first input node being configured to receive an inverted clock signal; a second pumping capacitor connected between a second input node and a second pumping node, the second input node being configured to receive a clock signal; a voltage outputting circuit connected to the first pumping node, the second pumping node and an output node, the voltage outputting circuit being configured to generate the negative voltage based on the clock signal and the inverted clock signal, and the output node being configured to output the negative voltage; a first discharging circuit configured to discharge the first pumping node; and a second discharging circuit configured to discharge the second pumping node, and wherein the first discharging circuit includes: a first n-type metal oxide semiconductor (NMOS) transistor connected between the first pumping node and a ground voltage, and including a gate electrode; and a first inverter configured to control a voltage of the gate electrode of the first NMOS transistor.

According to another aspect of the disclosure, there is provided a negative voltage generator including: a first pumping capacitor connected between a first input node and a first pumping node, the first input node being configured to receive an inverted clock signal; a second pumping capacitor connected between a second input node and a second pumping node, the second input node being configured to receive a clock signal; a first n-type metal oxide semiconductor (NMOS) transistor connected between the first pumping node and a ground voltage, and including a gate electrode connected to a first node; a first p-type metal oxide semiconductor (PMOS) transistor connected between the first input node and the first node, and including a gate electrode connected to the ground voltage; a second NMOS transistor connected between the first node and the first pumping node, and including a gate electrode connected to the ground voltage; a third NMOS transistor connected between the second pumping node and the ground voltage, and including a gate electrode connected to a second node; a second PMOS transistor connected between the second input node and the second node, and including a gate electrode connected to the ground voltage; a fourth NMOS transistor connected between the second node and the second pumping node, and including a gate electrode connected to the ground voltage; a fifth NMOS transistor connected between the first pumping node and an output node, and including a gate electrode connected to the second pumping node, and the output node being configured to output the negative voltage; a sixth NMOS transistor connected between the second pumping node and the output node, and including a gate electrode connected to the first pumping node; a load capacitor connected between the output node and the ground voltage; a first diode connected between the first pumping node and the output node; and a second diode connected between the second pumping node and the output node.

According to one or more embodiments of the disclosure, in the negative voltage generator and the memory device, the NMOS transistors may be used for discharging the pumping nodes. Accordingly, a voltage lower than a threshold voltage may not be required to turn on the NMOS transistors, and thus the pumping speed and performance of the negative voltage generator may be improved or enhanced. In addition, the majority carrier of the NMOS transistors may be electrons, which have negative properties. Since the carrier mobility of electrons is higher than the carrier mobility of holes by about two to three times, the pumping nodes may be discharged more efficiently when the NMOS transistors are used. Further, additional pumping capacitors and additional circuits may not be required, and thus the negative voltage generator may be implemented with relatively reduced circuit area and power consumption.

### BRIEF DESCRIPTION OF DRAWINGS

Illustrative, non-limiting example embodiments will be more clearly understood from the following detailed description taken in conjunction with the accompanying drawings, in which:

FIG. 1 is a block diagram illustrating a negative voltage generator according to one or more example embodiments;

FIG. 2 is a circuit diagram illustrating a negative voltage generator according to one or more example embodiments;

FIGS. 3A, 3B, 3C, are diagrams for describing an operation of a negative voltage generator of FIG. 2;

FIGS. 4A and 4B are diagrams for describing an overall operation of a negative voltage generator of FIG. 2;

FIGS. 5, 6, 7 and 8 are diagrams for describing performance of a negative voltage generator according to one or more example embodiments;

FIG. 9 is a block diagram illustrating a memory system including a memory device according to one or more example embodiments;

FIG. 10 is a block diagram illustrating a memory device according to one or more example embodiments;

FIG. 11 is a diagram illustrating an example of a memory cell included in a memory device of FIG. 10;

FIG. 12 is a block diagram illustrating a memory module that may be employed to a memory system according to one or more example embodiments; and

FIG. 13 is a block diagram illustrating an integrated circuit including a negative voltage generator according to one or more example embodiments.

### DETAILED DESCRIPTION

Various example embodiments will be described more fully with reference to the accompanying drawings, in which embodiments are shown. The disclosure may, however, be embodied in many different forms and should not be construed as limited to the embodiments set forth herein. Like reference numerals refer to like elements throughout this application.

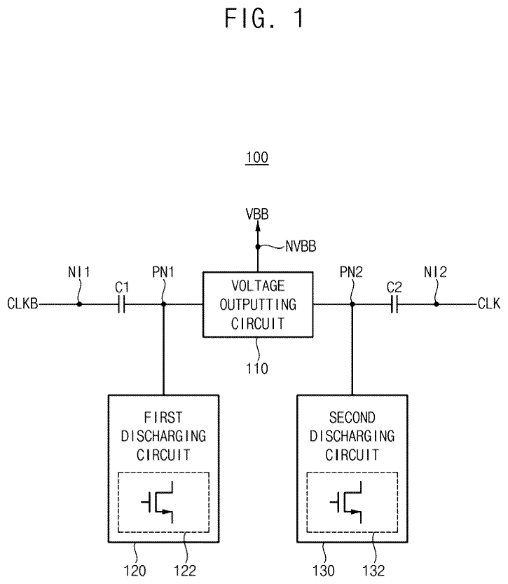

FIG. 1 is a block diagram illustrating a negative voltage generator according to one or more example embodiments.

Referring to FIG. 1, a negative voltage generator 100 includes a first pumping capacitor C1, a second pumping capacitor C2, a voltage outputting circuit 110, a first discharging circuit 120 and a second discharging circuit 130.

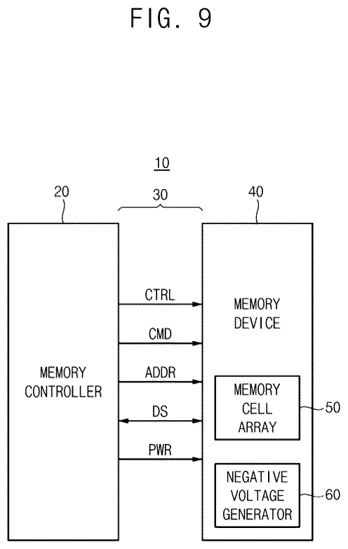

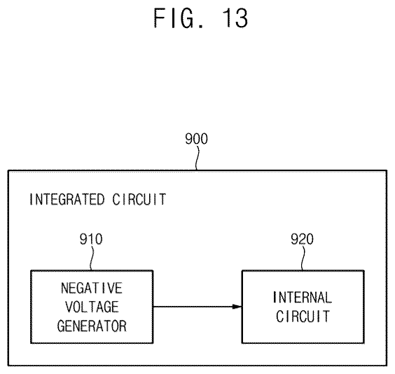

In some example embodiments, the negative voltage generator 100 may be included in a memory device, and may be used to provide or supply a negative voltage to the memory device. For example, the negative voltage generator 100 may generate a back-bias voltage that is supplied to a cell transistor included in a memory cell of the memory device, and the negative voltage generator 100 may be referred to as a back-bias voltage generator. However, example embodiments are not limited thereto, and the negative voltage generator 100 may be included in various electronic devices and/or electronic systems. Examples of various devices or systems including the negative voltage generator 100 will be described with reference to FIGS. 9 and 13.

The negative voltage generator 100 may generate a negative voltage VBB based on a clock signal CLK and an inverted clock signal CLKB. For example, the negative voltage VBB may have a voltage level lower than about 0V. For example, the clock signal CLK and the inverted clock signal CLKB may be signals that toggle or swing between a logic high level and a logic low level. For example, the clock signal CLK and the inverted clock signal CLKB may be signals that regularly or periodically toggle or swing between the logic high level and the logic low level. The clock signal CLK and the inverted clock signal CLKB may have opposite phases with the same period. For example, the negative voltage VBB may have a negative power supply voltage level that is obtained by multiplying a power supply voltage level by −1, and the power supply voltage level may correspond to the logic high level of the clock signal CLK and the inverted clock signal CLKB.

The first pumping capacitor C1 is connected between a first pumping node PN1 and a first input node NI1 that receives the inverted clock signal CLKB. The second pumping capacitor C2 is connected between a second pumping node PN2 and a second input node NI2 that receives the clock signal CLK. The first pumping node PN1 may be capacitively coupled by the first pumping capacitor C1 and the second pumping node PN2 may be capacitively coupled by the second pumping capacitor C2.

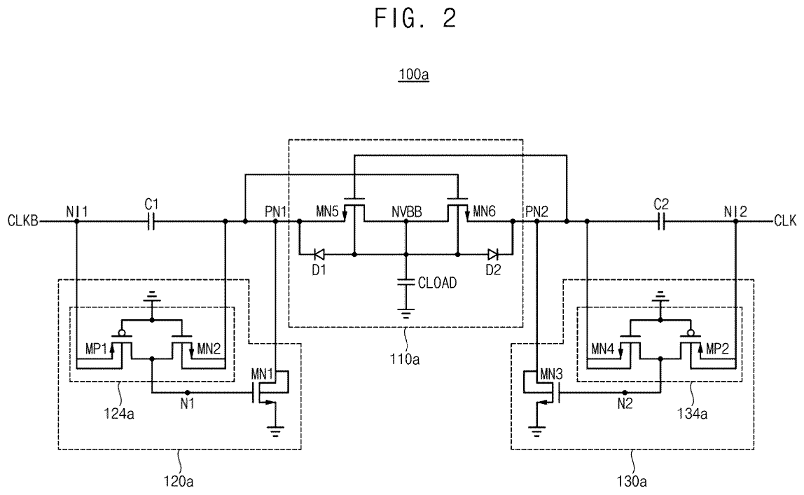

The voltage outputting circuit 110 is connected to the first pumping node PN1, the second pumping node PN2 and an output node NVBB that outputs the negative voltage VBB. The voltage outputting circuit 110 generates the negative voltage VBB based on the clock signal CLK and the inverted clock signal CLKB. For example, the voltage outputting circuit 110 may include cross-coupled transistors. An example of a circuit configuration of the voltage outputting circuit 110 will be described with reference to FIG. 2.

As described above, a configuration (or structure) in which the negative voltage generator 100 includes the pumping capacitors C1 and C2 and the cross-coupled transistors may be referred to as a cross-coupled hybrid pumping circuit (CHPC) configuration (or structure).

The first discharging circuit 120 discharges the first pumping node PN1. The first discharging circuit 120 may include an n-type metal oxide semiconductor (NMOS) transistor 122. In addition, according to an embodiment, the first discharging circuit 120 may further include a circuit for controlling a voltage of a gate electrode of the NMOS transistor 122.

The second discharging circuit 130 discharges the second pumping node PN2. A configuration of the second discharging circuit 130 may be substantially the same as the configuration of the first discharging circuit 120. For example, the second discharging circuit 130 may include an NMOS transistor 132. In addition, according to an embodiment, the second discharging circuit 130 may further include a circuit for controlling a voltage of a gate electrode of the NMOS transistor 132.

An example of circuit configurations of the first discharging circuit 120 and the second discharging circuit 130 will be described with reference to FIG. 2.

In a related art negative voltage generator with the CHPC configuration, p-type metal oxide semiconductor (PMOS) transistors were used to discharge pumping nodes (e.g., the pumping nodes PN1 and PN2). A PMOS transistor may have a characteristic that it is turned on when a voltage of a gate electrode is lower than a voltage of a source electrode by a threshold voltage, and a voltage lower than the threshold voltage may be required to turn on the PMOS transistor. However, the related art negative voltage generator had problems in that a voltage insufficient to turn on the PMOS transistor was provided and thus the pumping speed and performance of the negative voltage generator were degraded. In the related art negative voltage generators, the pumping speed and performance were improved by including additional pumping capacitors and/or additional circuits, however, the circuit area and power consumption increased.

In the negative voltage generator 100 according to one or more example embodiments, the NMOS transistors 122 and 132 may be used for discharging the pumping nodes PN1 and PN2. Accordingly, a voltage lower than a threshold voltage may not be required to turn on the NMOS transistors 122 and 132, and thus the pumping speed and performance of the negative voltage generator 100 may be improved or enhanced. In addition, the majority carrier of the NMOS transistors 122 and 132 may be electrons, which have negative properties. Since the carrier mobility of electrons is higher than that of holes by about two to three times, the pumping nodes PN1 and PN2 may be discharged more efficiently when the NMOS transistors 122 and 132 are used. Further, additional pumping capacitors and additional circuits may not be required, and thus the negative voltage generator 100 may be implemented with relatively reduced circuit area and power consumption.

FIG. 2 is a circuit diagram illustrating a negative voltage generator according to one or more example embodiments.

Referring to FIG. 2, a negative voltage generator 100a includes the first pumping capacitor C1, the second pumping capacitor C2, a voltage outputting circuit 110a, a first discharging circuit 120a and a second discharging circuit 130a. The descriptions repeated with or overlapping with descriptions of FIG. 1 will be omitted in the interest of brevity.

The first discharging circuit 120a may include a first NMOS transistor MN1 and a first inverter 124a.

The first NMOS transistor MN1 may include a first electrode (e.g., a drain electrode) connected to the first pumping node PN1, a second electrode (e.g., a source electrode) connected to a ground voltage, and a gate electrode connected to a first node N1. For example, the first NMOS transistor MN1 may be connected between the first pumping node PN1 and the ground voltage, and the gate electrode of the first NMOS transistor MN1 may be connected to the first node N1. In FIG. 2 and subsequent figures, three parallel straight lines with different lengths connected to the second electrode of the first NMOS transistor MN1 may represent the ground voltage.

The first inverter 124a may control the voltage of the gate electrode of the first NMOS transistor MN1. For example, the first inverter 124a may control the voltage at the first node N1. For example, an input terminal of the first inverter 124a may be connected to the ground voltage. As described above, a configuration of the first inverter 124a in which the input terminal is connected to the ground voltage may be referred to as a ground gated configuration.

The first inverter 124a may include a first PMOS transistor MP1 and a second NMOS transistor MN2.

The first PMOS transistor MP1 may include a first electrode (e.g., a source electrode) connected to the first input node NI1, a second electrode (e.g., a drain electrode) connected to the gate electrode of the first NMOS transistor MN1 (e.g., the first node N1), and a gate electrode connected to the ground voltage. For example, the first PMOS transistor MP1 may be connected between the first input node NI1 and the gate electrode of the first NMOS transistor MN1, and the gate electrode of the first PMOS transistor MP1 may be connected to the ground voltage.

The second NMOS transistor MN2 may include a first electrode (e.g., a drain electrode) connected to the gate electrode of the first NMOS transistor MN1 (e.g., the first node N1), a second electrode (e.g., a source electrode) connected to the first pumping node PN1, and a gate electrode connected to the ground voltage. For example, the second NMOS transistor MN2 may be connected between the gate electrode of the first NMOS transistor MN1 and the first pumping node PN1, and the gate electrode of the second NMOS transistor MN2 may be connected to the ground voltage.

In some example embodiments, a bulk electrode of the first PMOS transistor MP1 may be connected to the first input node NI1, and a bulk electrode of the first NMOS transistor MN1 and a bulk electrode of the second NMOS transistor MN2 may be connected to the first pumping node PN1. For example, a bulk electrode may refer to an electrode that is connected to the main body (or “bulk”) of a semiconductor material, as opposed to a surface or a gate electrode.

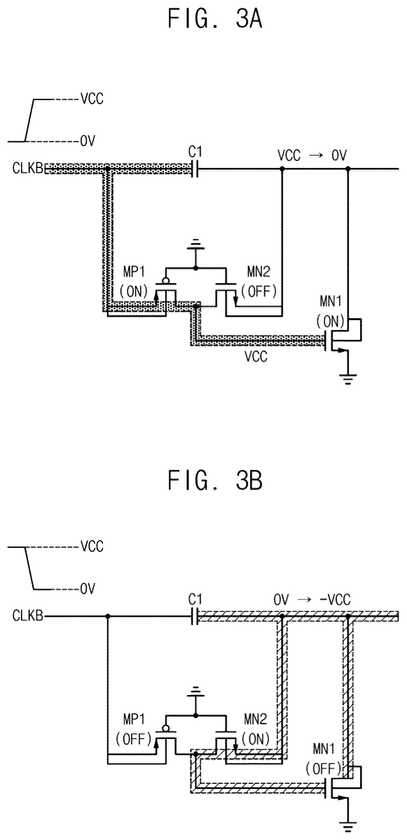

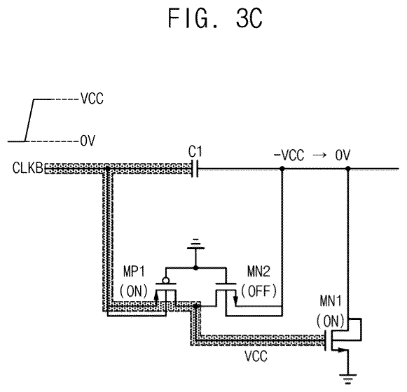

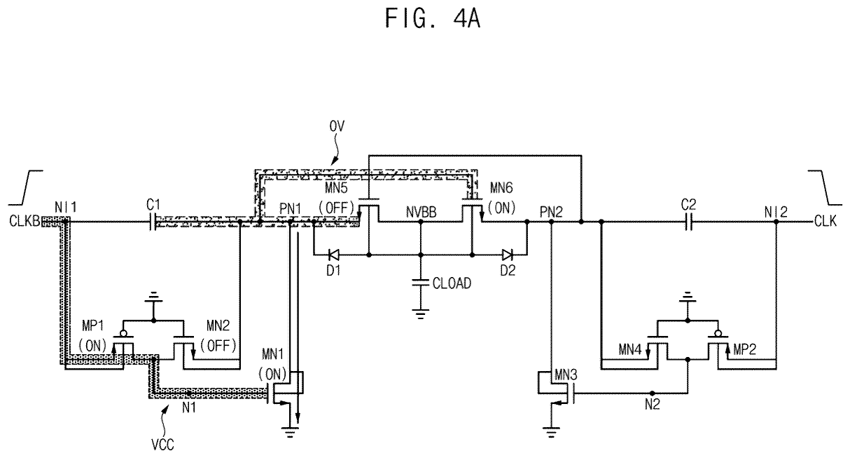

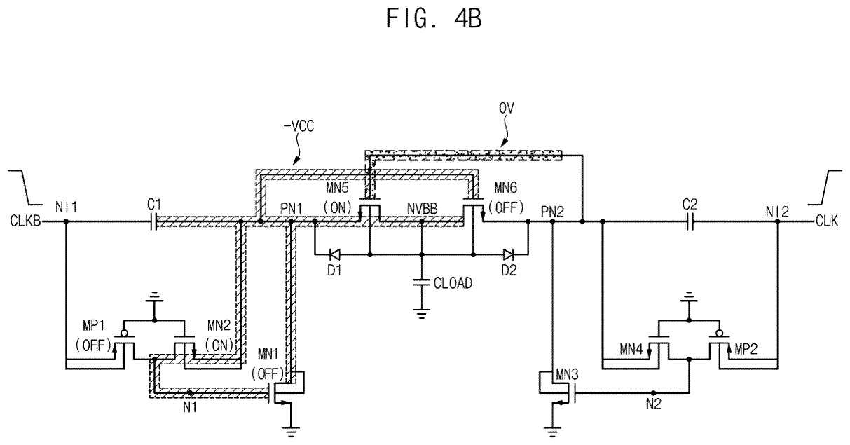

The first discharging circuit 120a may include the first NMOS transistor MN1 for discharging the first pumping node PN1 and the first inverter 124a with the ground gated configuration for controlling the voltage of the gate electrode of the first NMOS transistor MN1. As compared with the related art negative voltage generator including the PMOS transistor, a voltage lower than a threshold voltage of the first NMOS transistor MN1 may not be required, and thus relatively efficient operation may be implemented. An operation of the first discharging circuit 120a will be described with reference to FIGS. 3A, 3B, 3C, 4A and 4B.

The second discharging circuit 130a may include a third NMOS transistor MN3 and a second inverter 134a. The second discharging circuit 130a may have a configuration substantially the same as that of the first discharging circuit 120a.

The third NMOS transistor MN3 may include a first electrode (e.g., a drain electrode) connected to the second pumping node PN2, a second electrode (e.g., a source electrode) connected to the ground voltage, and a gate electrode connected to a second node N2. For example, the third NMOS transistor MN3 may be connected between the second pumping node PN2 and the ground voltage, and the gate electrode of the third NMOS transistor MN3 may be connected to the second node N2.

The second inverter 134a may control the voltage of the gate electrode of the third NMOS transistor MN3. For example, the second inverter 134a may control the voltage at the second node N2. For example, an input terminal of the second inverter 134a may be connected to the ground voltage.

The second inverter 134a may include a second PMOS transistor MP2 and a fourth NMOS transistor MN4.

The second PMOS transistor MP2 may include a first electrode (e.g., a source electrode) connected to the second input node NI2, a second electrode (e.g., a drain electrode) connected to the gate electrode of the third NMOS transistor MN3 (e.g., the second node N2), and a gate electrode connected to the ground voltage. For example, the second PMOS transistor MP2 may be connected between the second input node NI2 and the gate electrode of the third NMOS transistor MN3, and the gate electrode of the second PMOS transistor MP2 may be connected to the ground voltage.

The fourth NMOS transistor MN4 may include a first electrode (e.g., a drain electrode) connected to the gate electrode of the third NMOS transistor MN3 (e.g., the second node N2), a second electrode (e.g., a source electrode) connected to the second pumping node PN2, and a gate electrode connected to the ground voltage. For example, the fourth NMOS transistor MN4 may be connected between the gate electrode of the third NMOS transistor MN3 and the second pumping node PN2, and the gate electrode of the fourth NMOS transistor MN4 may be connected to the ground voltage.

In some example embodiments, a bulk electrode of the second PMOS transistor MP2 may be connected to the second input node NI2, and a bulk electrode of the third NMOS transistor MN3 and a bulk electrode of the fourth NMOS transistor MN4 may be connected to the second pumping node PN2.

The voltage outputting circuit 110a may include a fifth NMOS transistor MN5, a sixth NMOS transistor MN6, a load capacitor CLOAD, a first diode D1 and a second diode D2.

The fifth NMOS transistor MN5 may include a first electrode (e.g., a drain electrode) connected to the output node NVBB, a second electrode (e.g., a source electrode) connected to the first pumping node PN1, and a gate electrode connected to the second pumping node PN2. For example, the fifth NMOS transistor MN5 may be connected between the first pumping node PN1 and the output node NVBB, and the gate electrode of the fifth NMOS transistor MN5 may be connected to the second pumping node PN2.

The sixth NMOS transistor MN6 may include a first electrode (e.g., a drain electrode) connected to the output node NVBB, a second electrode (e.g., a source electrode) connected to the second pumping node PN2, and a gate electrode connected to the first pumping node PN1. For example, the sixth NMOS transistor MN6 may be connected between the second pumping node PN2 and the output node NVBB, and the gate electrode of the sixth NMOS transistor MN6 may be connected to the first pumping node PN1.

The load capacitor CLOAD may be connected between the output node NVBB and the ground voltage.

The first diode D1 may include a first electrode connected to the output node NVBB, and a second electrode connected to the first pumping node PN1. For example, the first diode D1 may be connected between the first pumping node PN1 and the output node NVBB. The first electrode of the first diode D1 may be an anode electrode and the second electrode of the first diode D1 may be a cathode electrode.

The second diode D2 may include a first electrode connected to the output node NVBB and a second electrode connected to the second pumping node PN2. For example, the second diode D2 may be connected between the second pumping node PN2 and the output node NVBB. The first electrode of the second diode D2 may be an anode electrode and the second electrode of the second diode D2 may be a cathode electrode.

FIGS. 3A, 3B, and 3C are diagrams for describing an operation of a negative voltage generator of FIG. 2.

Referring to FIGS. 3A, 3B and 3C, operations of the first NMOS transistor MN1, the first PMOS transistor MP1 and the second NMOS transistor MN2 that are included in the first discharging circuit 120a of FIG. 2 is illustrated. For convenience of illustration, only components C1, MN1, MP1 and MN2 that are directly connected to the first input node NI1, the first pumping node PN1 and the first node N1 are illustrated.

At an initial operation time, when the inverted clock signal CLKB transitions from a logic low level (e.g., about 0V) to a logic high level (e.g., a power supply voltage level VCC) as illustrated in FIG. 3A, a voltage at the first input node NI1 may have the power supply voltage level VCC, and the first PMOS transistor MP1 may be turned on. Based on the first PMOS transistor MP1 is turned on, the voltage at the first node N1 may increase to the power supply voltage level VCC. For example, when the first PMOS transistor MP1 is turned on, the voltage at the first node NI may increase to the power supply voltage level VCC. Since the first node N1 is connected to the gate electrode of the first NMOS transistor MN1, and since a gate-source voltage (e.g., VGS) of the first NMOS transistor MN1 corresponds to the power supply voltage level VCC and is sufficiently high to turn on the first NMOS transistor MN1, the first NMOS transistor MN1 may be turned on. A voltage at the first pumping node PN1 may increase to the power supply voltage level VCC due to the capacitive coupling at the beginning of operation, and then may decrease to about 0V when the first NMOS transistor MN1 is turned on. For example, when the inverted clock signal CLKB transitions from the logic low level to the logic high level, the voltage level of the first pumping node PN1 may decrease from the power supply voltage level VCC corresponding to the logic high level to a zero voltage level (e.g., about 0V) corresponding to the logic low level. The second NMOS transistor MN2 may be turned off.

Thereafter, when the inverted clock signal CLKB transitions from the logic high level to the logic low level as illustrated in FIG. 3B, the voltage at the first pumping node PN1 may decrease to a negative power supply voltage level −VCC, which is obtained by multiplying the power supply voltage level VCC by −1, by the capacitive coupling. When the voltage at the first pumping node PN1 decreases, the second NMOS transistor MN2 may be turned on, and the voltage at the first node N1 may also decrease to the negative power supply voltage level −VCC. Since the gate-source voltage (e.g., VGS) of the first NMOS transistor MN1 corresponds to the negative power supply voltage level −VCC, the first NMOS transistor MN1 may be turned off. For example, when the inverted clock signal CLKB transitions from the logic high level to the logic low level, the voltage level of the first pumping node PN1 may decrease from the zero voltage level to the negative power supply voltage level −VCC. The first PMOS transistor MP1 may be turned off.

Thereafter, when the inverted clock signal CLKB transitions from the logic low level to the logic high level again as illustrated in FIG. 3C, the first PMOS transistor MP1 and the first NMOS transistor MN1 may be turned on and the second NMOS transistor MN2 may be turned off, similarly to FIG. 3A. The voltage at the first pumping node PN1 may increase to about 0V by the capacitive coupling.

Thereafter, the inverted clock signal CLKB may toggle, and thus the operations of FIGS. 3B and 3C may be alternately and repeatedly performed. For example, the inverted clock signal CLKB may regularly or periodically toggle, and thus the operations of FIGS. 3B and 3C may be alternately and repeatedly performed.

FIGS. 4A and 4B are diagrams for describing an overall operation of a negative voltage generator of FIG. 2.

Referring to FIG. 4A, in an example case in which the inverted clock signal CLKB transitions from the logic low level to the logic high level, operations of the first NMOS transistor MN1, the operations of the first PMOS transistor MP1 and the second NMOS transistor MN2 may be substantially the same as those described with reference to FIGS. 3A and 3C.

In an example case in which the inverted clock signal CLKB transitions from the logic low level to the logic high level, the clock signal CLK may transition from the logic high level to the logic low level, and the second discharging circuit 130a may operate similarly to the first discharging circuit 120a of FIG. 3B. For example, the fourth NMOS transistor MN4 may be turned on, the third NMOS transistor MN3 and the second PMOS transistor MP2 may be turned off, and a voltage at the second pumping node PN2 may decrease to the negative power supply voltage level −VCC by the capacitive coupling.

In addition, since the voltage at the first pumping node PN1 has the zero voltage level and the voltage at the second pumping node PN2 has the negative power supply voltage level −VCC, the sixth NMOS transistor MN6 may be turned on, the fifth NMOS transistor MN5 may be turned off, and the output node NVBB may be electrically connected to the second pumping node PN2 having the negative power supply voltage level −VCC.

Thereafter, as illustrated in FIG. 4B, in an example case in which the inverted clock signal CLKB transitions from the logic high level to the logic low level, the operations of the first NMOS transistor MN1 the first PMOS transistor MP1 and the second NMOS transistor MN2 may be substantially the same as those described with reference to FIG. 3B.

In an example case in which the inverted clock signal CLKB transitions from the logic high level to the logic low level, the clock signal CLK may transition from the logic low level to the logic high level, and the second discharging circuit 130a may operate similarly to the first discharging circuit 120a of FIGS. 3A and 3C. For example, the second PMOS transistor MP2 and the third NMOS transistor MN3 may be turned on, the fourth NMOS transistor MN4 may be turned off, and the voltage at the second pumping node PN2 may increase to the power supply voltage level VCC and then may decrease to about 0V by the capacitive coupling.

In addition, since the voltage at the first pumping node PN1 has the negative power supply voltage level −VCC and the voltage at the second pumping node PN2 has the zero voltage level, the fifth NMOS transistor MN5 may be turned on, the sixth NMOS transistor MN6 may be turned off, and the output node NVBB may be electrically connected to the first pumping node PN1 having the negative power supply voltage level −VCC.

When a first operation of FIG. 4A in which the inverted clock signal CLKB transitions from the logic low level to the logic high level, and a second operation of FIG. 4B in which the inverted clock signal CLKB transitions from the logic high level to the logic low level, are alternately repeated, a voltage of the output node NVBB (e.g., the negative voltage VBB) may reach the negative power supply voltage level −VCC.

In the related art negative voltage generator with the CHPC configuration, PMOS transistors are used to discharge pumping nodes (e.g., the pumping nodes PN1 and PN2). However, in the negative voltage generator 100a according to one or more example embodiments, the first and third NMOS transistors MN1 and MN3 may be used for discharging the pumping nodes PN1 and PN2 and the inverters 124a and 134a with the ground gated configurations may be used for controlling the voltages of the gate electrodes of the first and third NMOS transistors MN1 and MN3. In an example case in which the clock signal increases (e.g., when the inverted clock signal CLKB transitions from the logic low level to logic high level), the node (e.g., the first pumping node PN1) whose voltage has increased by the capacitive coupling may be completely discharged. In an example case in which the clock signal decreases (e.g., when the inverted clock signal CLKB transitions from the logic high level to logic low level), the node (e.g., the first pumping node PN1) whose voltage has decreased by the capacitive coupling may be maintained to the negative power supply voltage level −VCC by the reverse-bias diode connection. Accordingly, the negative voltage generator 100a may efficiently operate. In addition, the bulk electrode of each of the first NMOS transistor MN1, the third NMOS transistor MN3, the first PMOS transistor MP1, the second PMOS transistor MP2, the second NMOS transistor MN2 and the fourth NMOS transistor MN4 may be physically connected to the source electrode of the corresponding transistors, so that the first NMOS transistor MN1, the third NMOS transistor MN3, the first PMOS transistor MP1, the second PMOS transistor MP2, the second NMOS transistor MN2 and the fourth NMOS transistor MN4 do not exceed their allowed voltage range. Thus, the voltage stress of the transistors may be reduced, and the negative voltage generator 100a may stably operate.

The majority carrier of the PMOS transistor may be holes, which have positive properties, while the majority carrier of the NMOS transistor may be electrons, which have negative properties. Therefore, the discharging operation may be efficiently performed when using the NMOS transistor. Moreover, the carrier mobility of electrons may be higher than that of holes by about two to three times, and thus the NMOS transistor may be more efficient than the PMOS transistor when discharging the voltage increased by the capacitive coupling to about 0V.

Additionally, in an example case which the inverters 124a and 134a with the ground gated configurations are used, the gate-source voltage (e.g., VGS) of the first NMOS transistor MN1 and the third NMOS transistor MN3 may be maintained to the power supply voltage level VCC even in the initial operation time. The power supply voltage level VCC may be sufficiently high to turn on the first NMOS transistor MN1 and the third NMOS transistor MN3, and the amount of drain current flowing through the first NMOS transistor MN1 and the third NMOS transistor MN3 may also be larger than that of the PMOS transistor. Accordingly, it may solve the problem of degraded operating speed caused by the gate electrode of the PMOS transistor being connected to an output node (e.g., the output node NVBB) in the related art negative voltage generator. Further, as compared with the related art negative voltage generators including additional pumping capacitors and/or additional circuits, there may be also advantages in terms of circuit area and power consumption

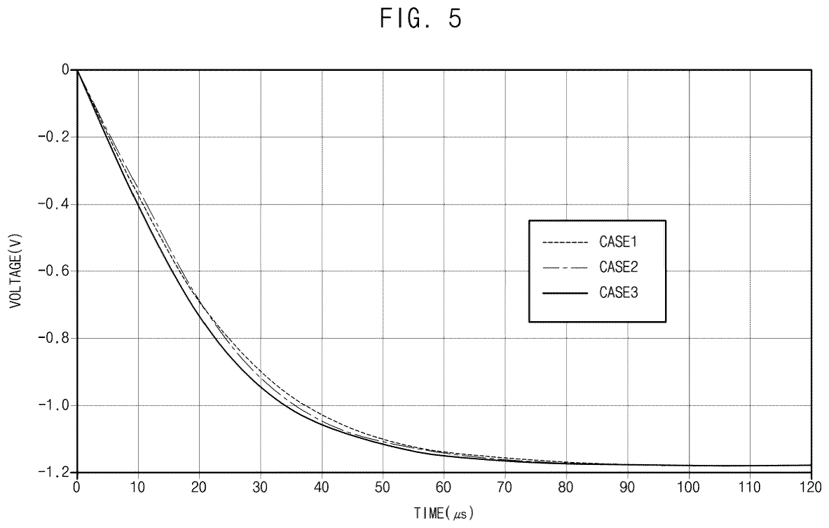

FIGS. 5, 6, 7 and 8 are diagrams for describing performance of a negative voltage generator according to one or more example embodiments.

Referring to FIGS. 5, 6, 7 and 8, “CASE1” represents the related art negative voltage generator that has the CHPC configuration and uses the PMOS transistor as the discharging transistor, “CASE2” represents the related art negative voltage generator including additional pumping capacitors and/or additional circuits as compared with “CASE1”, and “CASE3” represents the negative voltage generator according to one or more example embodiments that has the CHPC configuration and uses the NMOS transistor as the discharging transistor,

The simulations were performed using Virtuoso (Spectre) from Cadence, and the results were derived using about 180 nm complementary metal oxide semiconductor (CMOS) process. Various performances were simulated in various environments where the power supply voltage has about 0.7V to about 1.2V.

FIG. 5 illustrates the transient simulation results in an environment where the power supply voltage has about 1.2V (e.g. in a dual data rate four (DDR4) environment). For example, a capacitance of the pumping capacitor may be about 50 pF, a capacitance of the load capacitor may be about 10 nF, a clock frequency may be about 10 MHz, and a load current may be about 10 μA.

It can be seen that the negative voltage VBB generated from the negative voltage generator (e.g., CASE3) according to one or more example embodiments changes more sharply than the negative voltage generated from the related art negative voltage generators (e.g., CASE1 and CASE2). For example, a pump-down speed (or time) may be one of performance indicators of the negative voltage generator, and may represent a time to reach about −1.08V, which is about 90% of a target voltage level of about −1.2V. For example, the pump-down speed of the negative voltage generator (e.g., CASE3) according to one or more example embodiments may be about 42.6 μs, which is about 3 μs and about 1.2 μs shorter than the related art negative voltage generators (e.g., CASE1 and CASE2), respectively.

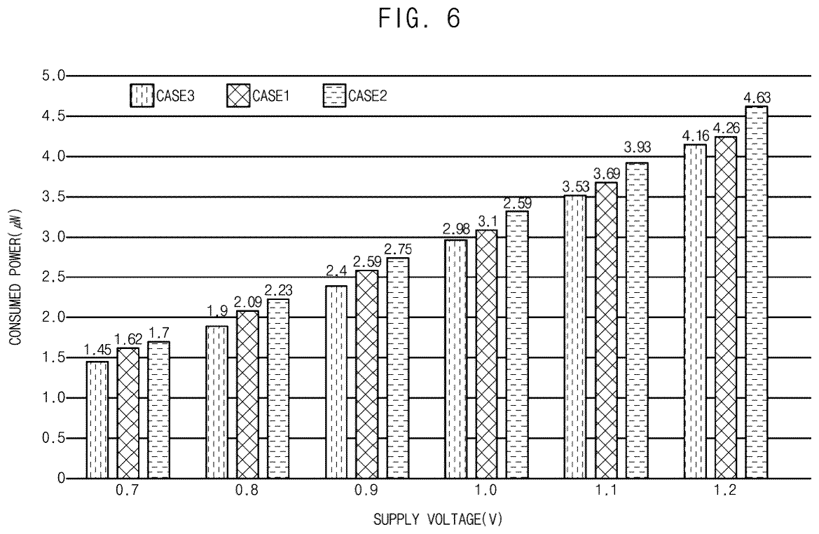

FIG. 6 illustrates the power consumption in a steady state in an environment where the power supply voltage has about 0.7V to about 1.2V. For example, the capacitance of the pumping capacitor may be about 50 pF, the capacitance of the load capacitor may be about 10 nF, and the clock frequency may be about 10 MHz.

It can be seen that the power consumption of the negative voltage generator (e.g., CASE3) according to one or more example embodiments is less than the power consumption of the related art negative voltage generators (e.g., CASE1 and CASE2). The PMOS transistor included in the related art negative voltage generators (e.g., CASE1 and CASE2) may have relatively low carrier mobility, a relatively large area may be required for the PMOS transistor, and thus the transistor with the relatively large area may consume relatively high power consumption. In contrast, the NMOS transistor included in the negative voltage generator (e.g., CASE3) according to one or more example embodiments may have relatively high carrier mobility, a relatively small area may be required for the NMOS transistor, and thus the negative voltage generator (e.g., CASE3) according to one or more example embodiments may achieve lower power consumption compared with the related art negative voltage generators (e.g., CASE1 and CASE2).

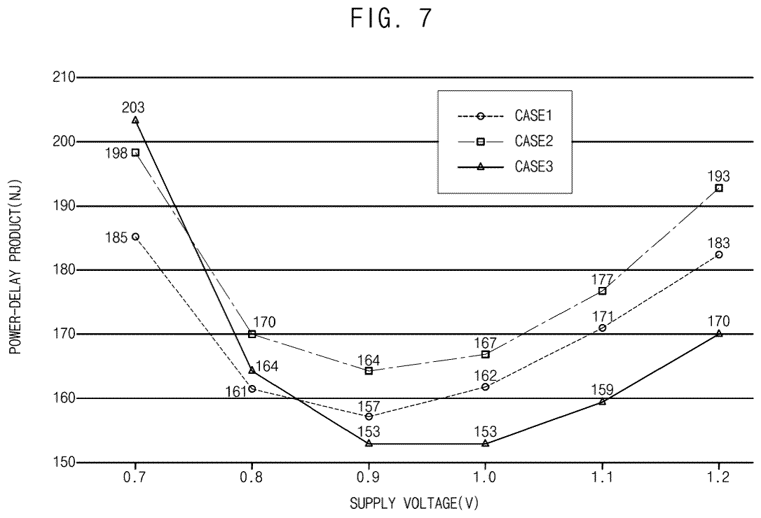

FIG. 7 illustrates the power-delay product (PDP) in an environment where the power supply voltage has about 0.7V to about 1.2V. For example, the capacitance of the pumping capacitor may be about 50 pF, and the capacitance of the load capacitor may be about 10 nF.

It can be seen that the negative voltage generator (e.g., CASE3) according to one or more example embodiments has a smaller PDP than the related art negative voltage generators (e.g., CASE1 and CASE2) when the power supply voltage has about 0.9V to about 1.2V. This may be caused by the fast transition speed and relatively low power consumption.

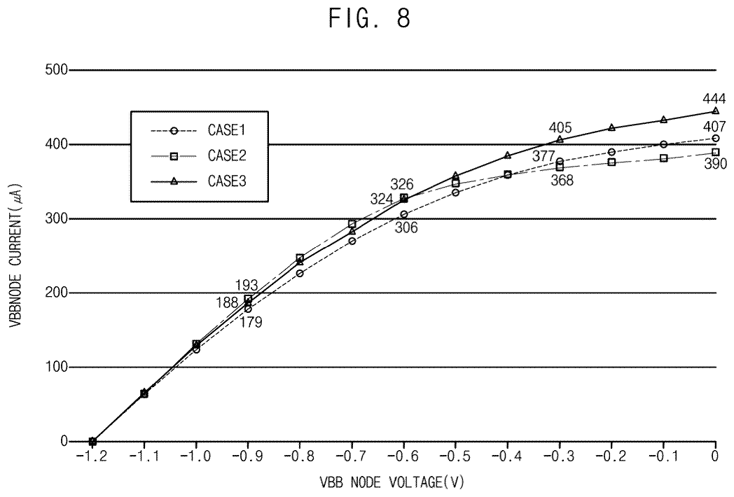

FIG. 8 illustrates the current drivability by measuring the current depending on the load voltage in an environment where the power supply voltage has about 1.2V. For example, the capacitance of the pumping capacitor may be about 50 pF, the capacitance of the load capacitor may be about 10 nF, and the clock frequency may be about 10 MHz.

It can be seen that the negative voltage generator (e.g., CASE3) according to one or more example embodiments has a relatively large amount of current in the initial operation time when the voltage at the output node NVBB has about 0V. In the related art negative voltage generators (e.g., CASE1 and CASE2), the voltage for turning on the PMOS transistor may be generated by repeat transition operation, and thus it may take long time for the PMOS transistor to reach the gate-source voltage (e.g., VGS) required to turn on the PMOS transistor. In contrast, in the negative voltage generator (e.g., CASE3) according to one or more example embodiments, the NMOS transistor may be turned on independently from such transition operation, and thus a relatively large amount of current may be generated in the initial operation time.

FIG. 9 is a block diagram illustrating a memory system including a memory device according to one or more example embodiments.

Referring to FIG. 9, a memory system 10 includes a memory controller 20 and a memory device 40. The memory system 10 may further include a plurality of signal lines 30 that electrically connect the memory controller 20 with the memory device 40.

The memory device 40 is controlled by the memory controller 20. For example, based on requests from a host, the memory controller 20 may store (e.g., write or program) data into the memory device 40, or may retrieve (e.g., read or sense) data from the memory device 40.

The plurality of signal lines 30 may include control lines, command lines, address lines, data input/output (I/O) lines and power lines. The memory controller 20 may transmit a command CMD, an address ADDR and a control signal CTRL to the memory device 40 via the command lines, the address lines and the control lines, may exchange a data signal DS with the memory device 40 via the data I/O lines, and may transmit a power supply voltage PWR to the memory device 40 via the power lines. According to an embodiment, the plurality of signal lines 30 may further include data strobe signal (DQS) lines for transmitting a DQS signal.

The memory device 40 includes a memory cell array 50 and a negative voltage generator 60. The memory cell array 50 includes a plurality of memory cells that store data. The negative voltage generator 60 provides a negative voltage to the plurality of memory cells.

The negative voltage generator 60 may be the negative voltage generator according to one or more example embodiments described with reference to FIGS. 1 through 8. For example, the negative voltage generator 60 may include the first and third NMOS transistors MN1 and MN3 for efficiently discharging the pumping nodes PN1 and PN2. For example, the negative voltage generator 60 may include the inverters 124a and 134a with the ground gated configurations for controlling the voltages of the gate electrodes of the first and third NMOS transistors MN1 and MN3, and thus it may solve the problem of degraded operating speed. For example, the negative voltage generator 60 may not include additional pumping capacitors and/or additional circuits, and there may be also advantages in terms of circuit area and power consumption.

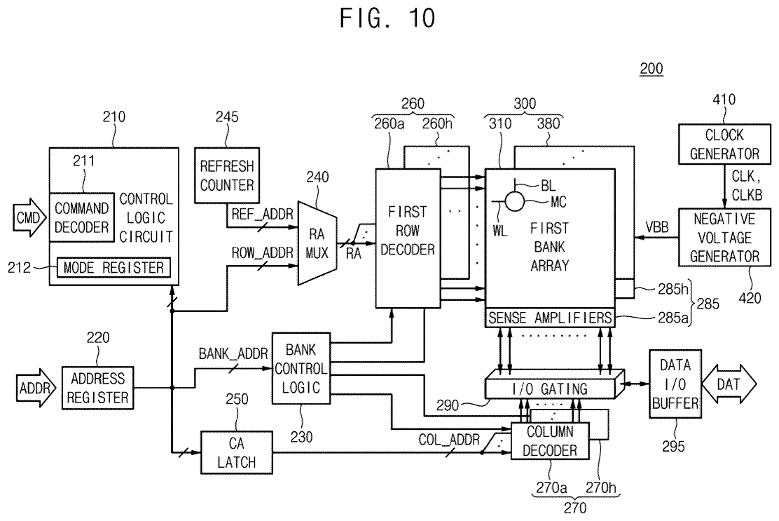

FIG. 10 is a block diagram illustrating a memory device according to one or more example embodiments.

Referring to FIG. 10, a memory device 200 may include a peripheral circuit and a memory cell array 300. The peripheral circuit may include a control logic circuit 210, an address register 220, a bank control logic circuit 230, a row address multiplexer 240, a refresh counter 245, a column address latch 250, a row decoder 260, a column decoder 270, a sense amplifier unit 285, an input/output (I/O) gating circuit 290, a data I/O buffer 295, a clock generator 410 and a negative voltage generator 420. For example, the memory device 200 may be one of various volatile memory devices such as a dynamic random access memory (DRAM).

The memory cell array 300 may include first to eighth bank arrays 310 to 380 (e.g., first to eighth bank arrays 310, 320, 330, 340, 350, 360, 370 and 380). The row decoder 260 may include first to eighth bank row decoders 260a to 260h connected respectively to the first to eighth bank arrays 310 to 380. The column decoder 270 may include first to eighth bank column decoders 270a to 270h connected respectively to the first to eighth bank arrays 310 to 380. The sense amplifier unit 285 may include first to eighth bank sense amplifiers 285a to 285h connected respectively to the first to eighth bank arrays 310 to 380.

The first to eighth bank arrays 310 to 380, the first to eighth bank row decoders 260a to 260h, the first to eighth bank column decoders 270a to 270h, and the first to eighth bank sense amplifiers 285a to 285h may form first to eighth banks. Each of the first to eighth bank arrays 310 to 380 may include a plurality of wordlines WL, a plurality of bitlines BL, and a plurality of memory cells MC that are at intersections of the wordlines WL and the bitlines BL.

Although FIG. 10 illustrates the memory device 200 including eight banks (and eight bank arrays, eight row decoders, and so on), the disclosure is not limited thereto, and as such, the memory device 200 may include any number of banks; for example, one, two, four, eight, sixteen, or thirty two banks, or any number therebetween one and thirty two.

The address register 220 may receive the address ADDR including a bank address BANK_ADDR, a row address ROW_ADDR, and a column address COL_ADDR from a memory controller (e.g., the memory controller 20 in FIG. 9). The address register 220 may provide the received bank address BANK_ADDR to the bank control logic circuit 230, may provide the received row address ROW_ADDR to the row address multiplexer 240, and may provide the received column address COL_ADDR to the column address latch 250.

The bank control logic circuit 230 may generate bank control signals in response to the bank address BANK_ADDR. One of the first to eighth bank row decoders 260a to 260h corresponding to the bank address BANK_ADDR may be activated in response to the bank control signals, and one of the first to eighth bank column decoders 270a to 270h corresponding to the bank address BANK_ADDR may be activated in response to the bank control signals.

The row address multiplexer 240 may receive the row address ROW_ADDR from the address register 220, and may receive a refresh row address REF_ADDR from the refresh counter 245. The row address multiplexer 240 may selectively output the row address ROW_ADDR or the refresh row address REF_ADDR as a row address RA. The row address RA that is output from the row address multiplexer 240 may be applied to the first to eighth bank row decoders 260a to 260h.

The activated one of the first to eighth bank row decoders 260a to 260h may decode the row address RA that is output from the row address multiplexer 240, and may activate in the corresponding bank array a wordline WL corresponding to the row address RA. For example, the activated bank row decoder may generate a wordline driving voltage, and may apply the wordline driving voltage to the wordline WL corresponding to the row address RA.

The column address latch 250 may receive the column address COL_ADDR from the address register 220, and may temporarily store the received column address COL_ADDR. In some one or more example embodiments, in a burst mode, the column address latch 250 may generate column addresses that increment from the received column address COL_ADDR. The column address latch 250 may apply the temporarily stored or generated column address to the first to eighth bank column decoders 270a to 270h.

The activated one of the first to eighth bank column decoders 270a to 270h may decode the column address COL_ADDR that is output from the column address latch 250, and may control the I/O gating circuit 290 to output data corresponding to the column address COL_ADDR.

The I/O gating circuit 290 may include circuitry configured to gate input/output data. The I/O gating circuit 290 may further include read data latches configured to store data that is output from the first to eighth bank arrays 310 to 380, and may also include write control devices for writing data to the first to eighth bank arrays 310 to 380.

Data DAT read from one of the first to eighth bank arrays 310 to 380 may be sensed by a sense amplifier connected to the one bank array from which the data DAT is to be read, and may be stored in the read data latches. The data DAT stored in the read data latches may be provided to the memory controller via the data I/O buffer 295. Data DAT to be written in one of the first to eighth bank arrays 310 to 380 may be provided to the I/O gating circuit 290 via the data I/O buffer 295 from the memory controller, and the I/O gating circuit 290 may write the data DAT in the one bank array through the write drivers.

The control logic circuit 210 may control operations of the memory device 200. For example, the control logic circuit 210 may generate control signals for the memory device 200 to perform the write operation and/or the read operation. The control logic circuit 210 may include a command decoder 211 that decodes a command CMD received from the memory controller, and a mode register 212 that sets an operation mode of the memory device 200. In some example embodiments, operations described herein as being performed by the control logic circuit 210 may be performed by processing circuitry. For example, the command decoder 211 may generate the control signals corresponding to the command CMD by decoding a write enable signal, a row address strobe signal, a column address strobe signal, a chip selection signal, etc.

The negative voltage generator 420 may provide a negative voltage VBB to a plurality of memory cells included in the memory cell array 300. The negative voltage generator 420 may be the negative voltage generator according to one or more example embodiments described with reference to FIGS. 1 through 8. For example, the negative voltage generator 420 may include the first and third NMOS transistors MN1 and MN3 for efficiently discharging the pumping nodes PN1 and PN2. For example, the negative voltage generator 420 may include the inverters 124a and 134a with the ground gated configurations for controlling the voltages of the gate electrodes of the first and third NMOS transistors MN1 and MN3, and thus it may solve the problem of degraded operating speed. For example, the negative voltage generator 420 may not include additional pumping capacitors and/or additional circuits, and there may be also advantages in terms of circuit area and power consumption.

The clock generator 410 may provide a clock signal CLK and an inverted clock signal CLKB to the negative voltage generator 420. The negative voltage generator 420 may generate the negative voltage VBB based on the clock signal CLK and the inverted clock signal CLKB.

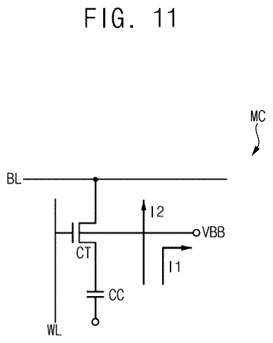

FIG. 11 is a diagram illustrating an example of a memory cell included in a memory device of FIG. 10.

Referring to FIG. 11, a memory cell MC may include a cell transistor CT connected to a wordline WL, a bitline BL, and a cell capacitor (or storage capacitor) CC. A junction leakage current I1 may occur due to defects in a junction boundary of the cell transistor CT, and a sub-threshold current I2 may occur due to a channel leakage current flowing through the cell transistor CT. To reduce the junction leakage current I1 and the sub-threshold current I2, a negative voltage (or back-bias voltage) VBB may be provided or supplied. For example, a threshold voltage of the cell transistor CT may increase by applying the negative voltage VBB to a bulk electrode of the cell transistor CT, and thus the leakage current may be reduced and data may be retained or preserved for a relatively long time without leakage.

As described above, the negative voltage generator according to one or more example embodiments may be used to provide or supply the negative voltage VBB. The negative voltage generator according to one or more example embodiments may have relatively fast operating speed, high current supply capability and low power consumption, and thus the memory device including the negative voltage generator according to one or more example embodiments may have improved or enhanced performance.

Although the memory device according to example embodiments is described based on a DRAM, the memory device according to example embodiments may be any volatile memory device, e.g., a static random access memory (SRAM), or the like, and/or may be any nonvolatile memory device, e.g., a phase random access memory (PRAM), a resistive random access memory (RRAM), a magnetic random access memory (MRAM), a ferroelectric random access memory (FRAM), or the like.

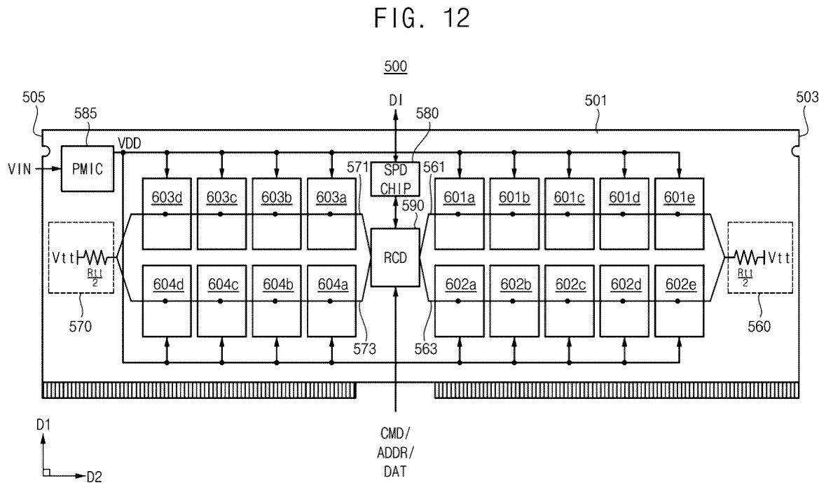

FIG. 12 is a block diagram illustrating a memory module that may be employed to a memory system according to one or more example embodiments.

Referring to FIG. 12, a memory module 500 may include a buffer chip 590 provided in or mounted on a circuit board 501, a plurality of memory devices 601a, 601b, 601c, 601d, 601e, 602a, 602a, 602c, 602d, 602e, 603a, 603b, 603c, 603d, 604a, 604b, 604c and 604d, module resistance units 560 and 570, a serial present detection (SPD) chip 580, and/or a power management integrated circuit (PMIC) 585.

The buffer chip 590 may control the semiconductor memory devices 601a to 601e, 602a to 602e, 603a to 603d and 604a to 604d, and the PMIC 585, under a control of a memory controller (e.g., the memory controller 20 in FIG. 9). For example, the buffer chip 590 may be a registered clock driver (RCD), and may receive an address ADDR, a command CMD and data DAT from the memory controller.

The SPD chip 580 may be a programmable read only memory (PROM) (e.g., an electrically erasable PROM (EEPROM)). The SPD chip 580 may include initial information and/or device information DI of the memory module 500. In some example embodiments, the SPD chip 580 may include the initial information and/or the device information DI such as a module form, a module configuration, a storage capacity, a module type, an execution environment, and/or the like of the memory module 500.

In an example case in which a memory system including the memory module 500 is booted up, the memory controller may read the device information DI from the SPD chip 580, and may recognize the memory module 500 based on the device information DI. The memory controller may control the memory module 500 based on the device information DI from the SPD chip 580. For example, the memory controller may recognize a type of the memory devices included in the memory module 500 based on the device information DI from the SPD chip 580.

Here, the circuit board 501 which is a printed circuit board (PCB) may extend in a second direction D2, perpendicular to a first direction D1, between a first edge portion 503 and a second edge portion 505. The first edge portion 503 and the second edge portion 505 may extend in the first direction D1. The buffer chip 590 may be provided on a center of the circuit board 501. The plurality of memory devices 601a to 601e, 602a to 602e, 603a to 603d and 604a to 604d may be arranged in a plurality of rows between the buffer chip 590 and the first edge portion 503, and between the buffer chip 590 and the second edge portion 505. In some example embodiments, operations described herein as being performed by the buffer chip 590 may be performed by processing circuitry.

In this example, the memory devices 601a to 601e and 602a to 602e may be arranged along a plurality of rows between the buffer chip 590 and the first edge portion 503. The memory devices 603a to 603d and 604a to 604d may be arranged along a plurality of rows between the buffer chip 590 and the second edge portion 505.

The buffer chip 590 may store the data DAT in the memory devices 601a to 601e, 602a to 602e, 603a to 603d and 604a to 604d. The buffer chip 590 may provide a command/address signal (e.g., CA) to the memory devices 601a to 601e through a command/address transmission line 561, and may provide a command/address signal to the memory devices 602a to 602e through a command/address transmission line 563. In addition, the buffer chip 590 may provide a command/address signal to the memory devices 603a to 603d through a command/address transmission line 571, and may provide a command/address signal to the memory devices 604a to 604d through a command/address transmission line 573.

The command/address transmission lines 561 and 563 may be connected in common to the module resistance unit 560 provided to be adjacent to the first edge portion 503, and the command/address transmission lines 571 and 573 may be connected in common to the module resistance unit 570 provided to be adjacent to the second edge portion 505. Each of the module resistance units 560 and 570 may include a termination resistor Rtt/2 connected to a termination voltage Vtt.

For example, each of the plurality of memory devices 601a to 601e, 602a to 602e, 603a to 603d and 604a to 604d may be the memory device according to one or more example embodiments described with reference to FIGS. 9 and 10. For example, each of the memory devices 601a to 601e, 602a to 602e, 603a to 603d and 604a to 604d may be a DRAM device, and may include the negative voltage generator according to one or more example embodiments described with reference to FIGS. 1 through 8.

The SPD chip 580 may be provided to be adjacent to the buffer chip 590, and the PMIC 585 may be provided between the memory device 603d and the second edge portion 505. The PMIC 585 may generate a power supply voltage VDD based on an input voltage VIN, and may provide the power supply voltage VDD to the memory devices 601a to 601e, 602a to 602e, 603a to 603d and 604a to 604d. In some example embodiments, the PMIC 585 may include the negative voltage generator according to example embodiments described with reference to FIGS. 1 through 8.

FIG. 13 is a block diagram illustrating an integrated circuit including a negative voltage generator according to one or more example embodiments.

Referring to FIG. 13, an integrated circuit 900 includes a negative voltage generator 910 and an internal circuit 920.

The negative voltage generator 910 may be the negative voltage generator according to example embodiments described with reference to FIGS. 1 through 8. For example, the negative voltage generator 910 may include the first and third NMOS transistors MN1 and MN3 for efficiently discharging the pumping nodes PN1 and PN2. For example, the negative voltage generator 910 may include the inverters 124a and 134a with the ground gated configurations for controlling the voltages of the gate electrodes of the first and third NMOS transistors MN1 and MN3, and thus it may solve the problem of degraded operating speed. For example, the negative voltage generator 910 may not include additional pumping capacitors and/or additional circuits, and there may be also advantages in terms of circuit area and power consumption. The internal circuit 920 may perform an operation based on a negative voltage VBB provided from the negative voltage generator 910. The operation may be a specific operation or a predetermined operation. The example embodiments may be applied to various electronic devices and systems that include the negative voltage generators. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IOT) device, an internet of everything (IoE) device, an e-book reader, a virtual reality (VR) device, an augmented reality (AR) device, a robotic device, a drone, an automotive, etc.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A negative voltage generator comprising:
a first pumping capacitor connected between a first input node and a first pumping node, the first input node being configured to receive an inverted clock signal;
a second pumping capacitor connected between a second input node and a second pumping node, the second input node being configured to receive a clock signal;
a voltage outputting circuit connected to the first pumping node, the second pumping node and an output node, the voltage outputting circuit being configured to generate the negative voltage based on the clock signal and the inverted clock signal, and the output node being configured to output the negative voltage;
a first discharging circuit configured to discharge the first pumping node; and
a second discharging circuit configured to discharge the second pumping node, and
wherein the first discharging circuit comprises:
a first n-type metal oxide semiconductor (NMOS) transistor connected between the first pumping node and a ground voltage, and comprising a gate electrode; and
a first inverter configured to control a voltage of the gate electrode of the first NMOS transistor.

2. The negative voltage generator of claim 1, wherein an input terminal of the first inverter is connected to the ground voltage.

3. The negative voltage generator of claim 2, wherein the first inverter comprises:
a first p-type metal oxide semiconductor (PMOS) transistor connected between the first input node and the gate electrode of the first NMOS transistor, the first PMOS transistor comprising a gate electrode connected to the ground voltage; and
a second NMOS transistor connected between the gate electrode of the first NMOS transistor and the first pumping node, the first PMOS transistor comprising a gate electrode connected to the ground voltage.

4. The negative voltage generator of claim 3, wherein a bulk electrode of the first PMOS transistor is connected to the first input node, and
wherein a bulk electrode of the first NMOS transistor and a bulk electrode of the second NMOS transistor are connected to the first pumping node.

5. The negative voltage generator of claim 3, wherein, based on the inverted clock signal transitioning from a logic low level to a logic high level, the first PMOS transistor and the first NMOS transistor are turned on, and a voltage level of the first pumping node decreases.

6. The negative voltage generator of claim 5, wherein, based on the inverted clock signal transitioning from the logic low level to the logic high level, the voltage level of the first pumping node decreases from a power supply voltage level corresponding to the logic high level to a zero voltage level corresponding to the logic low level.

7. The negative voltage generator of claim 5, wherein, based on the inverted clock signal transitioning from the logic high level to the logic low level, the second NMOS transistor is turned on, the first NMOS transistor is turned off, and the voltage level of the first pumping node further decreases.

8. The negative voltage generator of claim 7, wherein, based on the inverted clock signal transitioning from the logic high level to the logic low level, the voltage level of the first pumping node decreases from the zero voltage level to a negative power supply voltage level obtained by multiplying the power supply voltage level by −1.

9. The negative voltage generator of claim 8, wherein, based on the inverted clock signal transitioning from the logic high level to the logic low level, the first pumping node and the output node are electrically connected to each other.

10. The negative voltage generator of claim 7, wherein the negative voltage generator is configured to:
perform a first operation representing an operation in which the inverted clock signal transitions from the logic low level to the logic high level, and a second operation representing an operation in which the inverted clock signal transitions from the logic high level to the logic low level, and
wherein, when the first operation and the second operation are alternately repeated, a voltage level of the output node reaches a negative power supply voltage level obtained by multiplying the power supply voltage level by −1.

11. The negative voltage generator of claim 1, wherein the second discharging circuit comprises:
a third NMOS transistor connected between the second pumping node and the ground voltage, and comprising a gate electrode; and
a second inverter configured to control a voltage of the gate electrode of the third NMOS transistor.

12. The negative voltage generator of claim 11, wherein an input terminal of the second inverter is connected to the ground voltage.

13. The negative voltage generator of claim 12, wherein the second inverter comprises:
a second PMOS transistor connected between the second input node and the gate electrode of the third NMOS transistor, and having comprising a gate electrode connected to the ground voltage; and
a fourth NMOS transistor connected between the gate electrode of the third NMOS transistor and the second pumping node, and comprising a gate electrode connected to the ground voltage.

14. The negative voltage generator of claim 13, wherein a bulk electrode of the second PMOS transistor is connected to the second input node, and
wherein a bulk electrode of the third NMOS transistor and a bulk electrode of the fourth NMOS transistor are connected to the second pumping node.

15. The negative voltage generator of claim 1, wherein the voltage outputting circuit comprises:
a fifth NMOS transistor connected between the first pumping node and the output node, and comprising a gate electrode connected to the second pumping node;
a sixth NMOS transistor connected between the second pumping node and the output node, and comprising a gate electrode connected to the first pumping node; and
a load capacitor connected between the output node and the ground voltage.

16. The negative voltage generator of claim 15, wherein the voltage outputting circuit further comprises:
a first diode connected between the first pumping node and the output node; and
a second diode connected between the second pumping node and the output node.

17. A memory device comprising:
a memory cell array comprising a plurality of memory cells; and
a negative voltage generator configured to provide a negative voltage to the plurality of memory cells, the negative voltage generator comprising:
a first pumping capacitor connected between a first input node and a first pumping node, the first input node being configured to receive an inverted clock signal;
a second pumping capacitor connected between a second input node and a second pumping node, the second input node being configured to receive a clock signal;
a voltage outputting circuit connected to the first pumping node, the second pumping node and an output node, the voltage outputting circuit being configured to generate the negative voltage based on the clock signal and the inverted clock signal, and the output node being configured to output the negative voltage;
a first discharging circuit configured to discharge the first pumping node; and
a second discharging circuit configured to discharge the second pumping node, and
wherein the first discharging circuit comprises:
a first n-type metal oxide semiconductor (NMOS) transistor connected between the first pumping node and a ground voltage, and comprising a gate electrode; and
a first inverter configured to control a voltage of the gate electrode of the first NMOS transistor.

18. The memory device of claim 17, further comprising:
a clock generator configured to provide the clock signal and the inverted clock signal.

19. The memory device of claim 17, wherein the memory device is a dynamic random access memory (DRAM) device.

20. A negative voltage generator comprising:
a first pumping capacitor connected between a first input node and a first pumping node, the first input node being configured to receive an inverted clock signal;
a second pumping capacitor connected between a second input node and a second pumping node, the second input node being configured to receive a clock signal;
a first n-type metal oxide semiconductor (NMOS) transistor connected between the first pumping node and a ground voltage, and comprising a gate electrode connected to a first node;
a first p-type metal oxide semiconductor (PMOS) transistor connected between the first input node and the first node, and comprising a gate electrode connected to the ground voltage;
a second NMOS transistor connected between the first node and the first pumping node, and comprising a gate electrode connected to the ground voltage;
a third NMOS transistor connected between the second pumping node and the ground voltage, and comprising a gate electrode connected to a second node;
a second PMOS transistor connected between the second input node and the second node, and comprising a gate electrode connected to the ground voltage;
a fourth NMOS transistor connected between the second node and the second pumping node, and comprising a gate electrode connected to the ground voltage;
a fifth NMOS transistor connected between the first pumping node and an output node, and comprising a gate electrode connected to the second pumping node, and the output node being configured to output the negative voltage;
a sixth NMOS transistor connected between the second pumping node and the output node, and comprising a gate electrode connected to the first pumping node;
a load capacitor connected between the output node and the ground voltage;
a first diode connected between the first pumping node and the output node; and
a second diode connected between the second pumping node and the output node.
